(19) United States
(12) Patent Application Publication
(10) Pub. No.: US 2024/0309272 A1
(43) Pub. Date: Sep. 19, 2024

(54) COMPOSITION AND METHOD FOR SELECTIVELY ETCHING SILICON NITRIDE

(71) Applicant: ENTEGRIS, INC., Billerica, MA (US)

(72) Inventors: Juhee Yeo, Suwon (KR); SeongJin Hong, Cheongju-si (KR); WonLae Kim, Gunpo-si (KR); Younghun Park, Seoul (KR); Yeonhui Kang, Seoul (KR); Jinwook Jeong, Suwon-si (KR)

(21) Appl. No.: 18/607,272

(22) Filed: Mar. 15, 2024

Related U.S. Application Data
(60) Provisional application No. 63/452,362, filed on Mar. 15, 2023.

(51) Int. Cl. C09K 13/06

(52) U.S. Cl. CPC C09K 13/06

(57) ABSTRACT

Compositions and methods for selectively etching silicon nitride relative to polysilicon, silicon oxide materials and/or silicide materials from a microelectronic device.

### FIELD

The present disclosure relates to the field of compositions and methods for selectively etching silicon nitride.

### PRIORITY

The present disclosure claims priority to and benefit of U.S. provisional patent number 63/452,362 with a filing date of Mar. 15, 2023.

### BACKGROUND

Self-aligned poly-silicon gate structures include layers of silicon nitride that must be selectively removed. Removing the silicon nitride from other gate structure materials, such as polysilicon, silicon oxide, and metal silicate, remains an ongoing challenge. Another ongoing challenge is the high amount of foam generated during silicon nitride etching and the regrowth of silicon.

### SUMMARY

Some embodiments of the present disclosure relate to a composition that comprises a phosphoric acid, a water, and an alkyl silane compound of the formula:

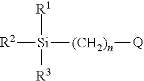

where:
R¹, R², and R³ are each independently a hydrogen, a halide, a hydroxide, an alkyl, or an alkoxide;
n is at least 1; and
Q is:

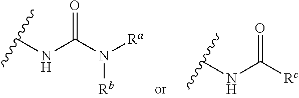

where:
R^{a} and R^{b} are each independently a hydrogen, an alkyl, a cycloalkyl, an aryl, an alkaryl, an aralkyl, or an alkoxyalkyl; and
R^{c} is a hydrogen, an alkyl, a cycloalkyl, an aryl, or an alkaryl.

In some embodiments, R¹, R², and R³ are each a methoxy.

In some embodiments, R^{a} and R^{b} are hydrogen.

In some embodiments, R^{a} is hydrogen and Rb is an alkyl.

In some embodiments, n is 1 to 6.

In some embodiments, the alkyl silane compound is a compound of the formula:

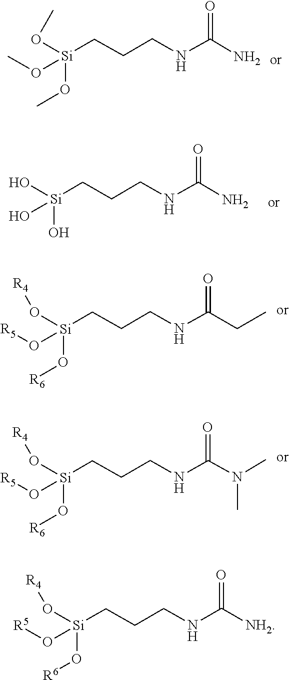

where:
R⁴, R⁵, and R⁶ are independently a methyl, an ethyl, an isopropyl, an n-propyl, an n-butyl, a sec-butyl, a tert-butyl, an isomer thereof.

In some embodiments, the composition comprises 75% to 90% by weight of the phosphoric acid based on a total weight of the composition.

In some embodiments, the composition comprises 10% to 20% by weight of the water based on a total weight of the composition.

In some embodiments, the composition comprises 0.01% to 5% by weight of the alkyl silane compound based on a total weight of the composition.

In some embodiments, the composition, when mixed at 200 RPM and at 25° C. to 160° C., produces less foam than a composition which does not comprise the alkyl silane compound.

Some embodiments relate to a method that comprises obtaining a structure comprising a silicon nitride and a silicon oxide and contacting the structure with a composition to remove at least a portion of the silicon nitride.

In some embodiments, the composition comprises a phosphoric acid, a water, and an alkyl silane compound of the formula:

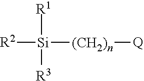

where:
R¹, R², and R³ are each independently a hydrogen, a halide, a hydroxide, an alkyl, or an alkoxide, n is at least 1, and Q is:

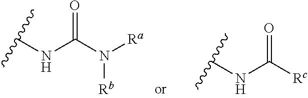

where:
R^{a} and R^{b} are each independently a hydrogen, an alkyl, a cycloalkyl, an aryl, an alkaryl, an aralkyl, or an alkoxyalkyl and R^{c} is a hydrogen, an alkyl, a cycloalkyl, an aryl, or an alkaryl.

In some embodiments, R¹, R², and R³ are each a methoxy.

In some embodiments, R^{a} and R^{b} are hydrogen.

In some embodiments, R^{a} is hydrogen and R^{b} is an alkyl.

In some embodiments, n is 1 to 6.

In some embodiments, the alkyl silane compound is a compound of the formula:

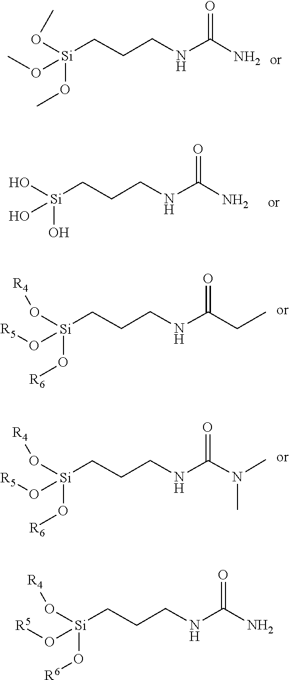

where:
R⁴, R⁵, and R⁶ are independently a methyl, an ethyl, an isopropyl, an n-propyl, an n-butyl, a sec-butyl, a tert-butyl, an isomer thereof.

In some embodiments, the composition comprises 75% to 90% by weight of the phosphoric acid based on a total weight of the composition.

In some embodiments, the composition comprises 10% to 20% by weight of the water based on a total weight of the composition.

In some embodiments, the composition comprises 0.01% to 5% by weight of the alkyl silane compound based on a total weight of the composition.

In some embodiments, the composition removes a greater proportion of the silicon nitride than the silicon oxide.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flow chart of a method for selectively etching silicon nitride, according to some embodiments.

FIG. 2 is an illustration of the results of the method of FIG. 1, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “alkyl” refers to a hydrocarbon compound having from 1 to 30 carbon atoms. An alkyl having n carbon atoms may be designated as a “Cₙ alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is linear. In some embodiments, the alkyl is branched. In some embodiments, the alkyl is substituted. In some embodiments, the alkyl is unsubstituted. In some embodiments, the alkyl comprises or is selected from the group consisting of at least one of a C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₈-C₁₀ alkyl, a C₂-C₉ alkyl, a C₂-C₈ alkyl, a C₂-C₇ alkyl, a C₂-C₆ alkyl, a C₂-C₅ alkyl, a C₃-C₅ alkyl, or any combination thereof. In some embodiments, the alkyl comprises or is selected from the group consisting of at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, heptyl, octyl, nonyl, decyl, dodecyl, octadecyl, or any combination thereof.

As used herein, the term “alkyl” refers to a hydrocarbon chain radical having from 1 to 30 carbon atoms. The alkyl may be attached via a single bond. An alkyl having n carbon atoms may be designated as a “Cₙ alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is saturated (e.g., single bonds). In some embodiments, the alkyl is unsaturated (e.g., double bonds and/or triple bonds). In some embodiments, the alkyl is linear. In some embodiments, the alkyl is branched. In some embodiments, the alkyl is substituted. In some embodiments, the alkyl is unsubstituted. In some embodiments, the alkyl may comprise, consist of, or consist essentially of, or may be selected from the group consisting of, at least one of a C₁-C₁₂ alkyl, a C₁-C₁₁ alkyl, a C₁-C₁₀ alkyl, a C₁-C₉ alkyl, a C₁-C₈ alkyl, a C₁-C₇ alkyl, a C₁-C₆ alkyl, a C₁-C₄ alkyl, a C₁-C₃ alkyl, or any combination thereof. In some embodiments, the alkyl may comprise, consist of, or consist essentially of, or may be selected from the group consisting of, at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, octyl, decyl, dodecyl, octadecyl, or any combination thereof.

As used herein, the term “alkoxy” refers to a radical of formula-OR, wherein R is an alkyl, as defined herein. In some embodiments, the alkoxy may comprise, consist of, or consist essentially of, or may selected from the group consisting of, at least one of methoxy, ethoxy, n-propoxy, 1-methylethoxy (isopropoxy), n-butoxy, iso-butoxy, sec-butoxy, tert-butoxy, or any combination thereof.

As used herein, the term “halide” refers to a —Cl, —Br, —I, or —F.

As used herein, the term “cycloalkyl” refers to a non-aromatic carbocyclic ring radical attached via a single bond and having from 3 to 8 carbon atoms in the ring. The term includes a monocyclic non-aromatic carbocyclic ring and a polycyclic non-aromatic carbocyclic ring. For example, two or more cycloalkyls may be fused, bridged, or fused and bridged to obtain the polycyclic non-aromatic carbocyclic ring. In some embodiments, the cycloalkyl may comprise, consist of, or consist essentially of, or may be selected from the group consisting of, at least one of cyclopropyl, cyclobutyl, cyclopentyl, cyclohexyl, cycloheptyl, cyclooctyl, or any combination thereof.

As used herein, the term “aryl” refers to an aromatic ring comprising carbon and hydrogen atoms. Examples of aryls include, without limitation, phenyl, biphenyl, napthyl, and the like.

As used herein, “silicon nitride” and “Si₃N₄” correspond to pure silicon nitride (Si₃N₄) as well as impure silicon nitride including hydrogen, carbon and/or oxygen impurities in the crystal structure.

As used herein, “silicon oxide” refers to thin films made of silicon oxide (SiOx), e.g., SiO₂, “thermal oxide” (ThOx), and the like. The silicon oxide can be placed on the substrate by any method, such as by deposition via chemical vapor deposition from TEOS or another source, or by being thermally deposited. The silicon oxide generally contains a commercially useful low level of other materials or impurities. The silicon oxide may be present as part of a microelectronic device substrate as a feature of the microelectronic device, for example as an insulating layer.

As used herein, “removing” corresponds to the removal of at least a portion of the exposed silicon nitride layer. For example, partial removal of silicon nitride material includes the anisotropic removal of a silicon nitride layer that covers/protects the gate electrodes to form a SisN4 sidewall. It is also contemplated herein that the compositions of the present invention may be used more generally to substantially remove silicon nitride material relative to poly-silicon and/or silicon oxide layers. In those circumstances, “substantial removal” is defined in one embodiment as at least 90%, in another embodiment at least 95%, and in yet another embodiment at least 99% of the silicon nitride material is removed using the compositions of the invention.

Some embodiments relate to a composition and method for the selective removal of silicon nitride from a microelectronic device, such as, and without limitation, a 3D NAND structure, flat panel display, microelectromechanical systems (MEMS), integrated circuit, or computer chip. The selective removal of silicon nitride by the present composition can prevent damage to the underlying silicon oxide layer and improve reliability of a semiconductor device, reduce foaming, and suppress silicon regrowth. In some embodiments, the composition may include phosphoric acid (H₃PO₄), water (H₂O), and an alkyl silane compound of the formula:

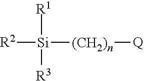

where:
R¹, R², and R³ are each independently a hydrogen, a halide, a hydroxide, an alkyl, or an alkoxide;
n is at least 1;
and Q is:

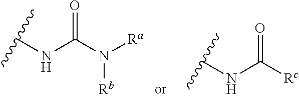

where:
R^{a} and R^{b} are each independently a hydrogen, an alkyl, a cycloalkyl, an aryl, an alkaryl, an aralkyl, or an alkoxyalkyl; and
R^{c} is a hydrogen, an alkyl, a cycloalkyl, an aryl, or an alkaryl.

In some embodiments, R¹, R², and R³ are each methoxy.

In some embodiments, R^{a} and R^{b} are hydrogen.

In some embodiments, R^{a} is hydrogen and R^{b} is an alkyl.

In some embodiments, n is 1 to 6.

In some embodiments, the alkyl silane compound is a compound of the formula:

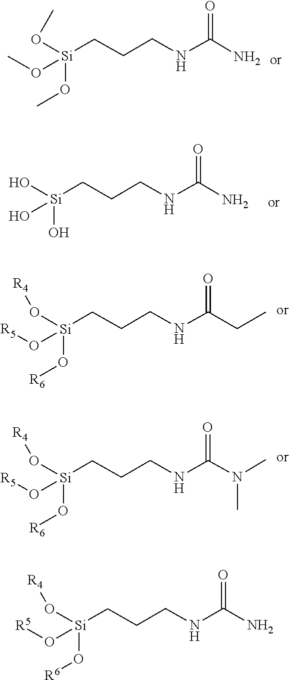

where:
R⁴, R⁵, and R⁶ are independently a methyl, an ethyl, an isopropyl, an n-propyl, an n-butyl, a sec-butyl, a tert-butyl, an isomer thereof.

In some embodiments, the composition comprises 75% to 90% by weight of the phosphoric acid based on a total weight of the composition, or any range or subrange between 75% to 90%. For example, in some embodiments, the percent by weight of phosphoric acid based on the total weight of the composition may be 80% to 90% or 85% to 90%. In some embodiments, the percent by weight of phosphoric acid based on the total weight of the composition may be 76% to 90%, 77% to 90%, 78% to 90%, 79% to 90%, 80% to 90%, 81% to 90%, 82% to 90%, 83% to 90%, 84% to 90%, 85% to 90%, 86% to 90%, 87% to 90%, 88% to 90%, or 89% to 90%. In some embodiments, the percent by weight of phosphoric acid based on the total weight of the wet etch composition may be 75% to 89%, 75% to 88%, 75% to 87%, 75% to 86%, 75% to 85%, 75% to 84%, 75% to 83%, 75% to 82%, 75% to 81%, 75% to 80%, 75% to 79%, 75% to 78%, 75% to 77%, or 75% to 76%.

In some embodiments, the composition comprises 10% to 20% by weight of the water based on a total weight of the composition, or any range or subrange between 1% to 20%. For example, in some embodiments, the percent by weight of the water based on the total weight of the composition may be 1% to 15%, 1% to 10%, or 5% to 20%. In some embodiments, the percent by weight of the water based on the total weight of the composition may be 2% to 20%, 3% to 20%, 4% to 20%, 5% to 20%, 6% to 20%, 7% to 20%, 8% to 20%, 9% to 20%, 10% to 20%, 11% to 20%, 12% to 20%, 13% to 20%, 14% to 20%, 15% to 20%, 16% to 20%, 17% to 20%, 18% to 20%, or 19% to 20%. In some embodiments, the percent by weight of the water based on the total weight of the composition may be 1% to 19%, 1% to 18%, 1% to 17%, 1% to 16%, 1% to 15%, 1% to 14%, 1% to 13%, 1% to 12%, 1% to 11%, 1% to 10%, 1% to 9%, 1% to 8%, 1% to 7%, 1% to 6%, 1% to 5%, 1% to 4%, 1% to 3%, or 1% to 2%.

In some embodiments, the composition comprises 0.01% to 5% by weight of the alkyl silane compound based on a total weight of the composition, or any range or subrange between 0.01% and 5%. For example, in some embodiments, the percent by weight of the alkyl silane compound based on the total weight of the composition may be 0.1% to 5%, 0.5% to 5%, 1% to 5%, 1.5% to 5%, 2% to 5%, 2.5% to 5%, 3% to 5%, 3.5% to 5%, 4% to 5%, or 4.5% to 5%. In some embodiments, the percent by weight of the alkyl silane compound based on the total weight of the composition may be 0.1% to 5%, 0.1% to 4%, 0.1% to 3%, 0.1% to 2%, or 0.1% to 1%. In some embodiments, the percent by weight of the alkyl silane compound based on the total weight of the composition may be 0.1% to 5%, 0.5% to 5%, 1% to 5%, 1.5% to 5%, 2% to 5%, 2.5% to 5%, 3% to 5%, 3.5% to 5%, 4% to 5%, or 4.5% to 5%. In some embodiments, the percent by weight of the alkyl silane compound based on the total weight of the composition may be 0.01% to 5%, 0.01% to 4.5%, 0.01% to 4%, 0.01% to 3.5%, 0.01% to 3%, 0.01% to 2.5%, 0.01% to 2%, 0.01% to 1.5%, 0.01% to 1%, 0.01% to 0.5%, or 0.01% to 0.1%.

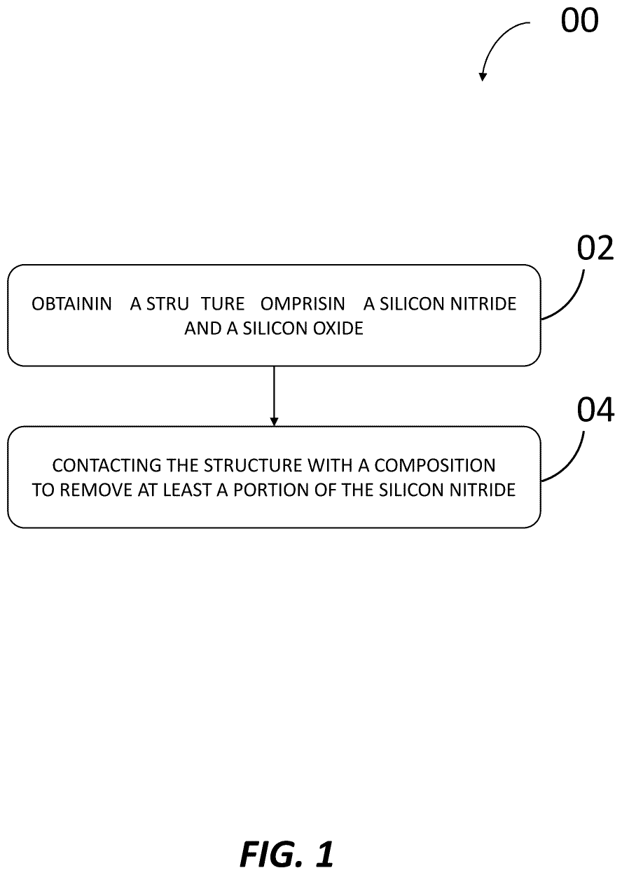

FIG. 1 is a flow chart of a method 100 for selectively etching silicon nitride, according to some embodiments. As shown in FIG. 1, the method 100 may comprise one or more of the following steps: a step 102 of obtaining a structure comprising a silicon nitride and a silicon oxide; and a step 104 of contacting the structure with a composition to remove at least a portion of the silicon nitride.

In some embodiments, the structure of step 102 may be part of a microelectronic device, such as, and without limitation, a 3D NAND structure, flat panel display, microelectromechanical systems (MEMS), integrated circuit, or computer chip.

In some embodiments, the contacting of step 104 comprises bringing into direct contact, or immediate or close proximity. In some embodiments, the contacting comprises disposing, depositing, applying, or adding the composition dropwise onto the structure. In some embodiments, the contacting is performed under heating.

In some embodiments, the contacting of step 104 is performed under temperatures between 25° C. to 180° C., or any range or subrange between 25° C. to 180° C. For example, in some embodiments, the temperature may be 30° C. to 180° C., 40° C. to 180° C., 50° C. to 180° C., 60° C. to 180° C., 70° C. to 180° C., 80° C. to 180° C., 90° C. to 180° C., 100° C. to 180° C., 110° C. to 180° C., 120° C. to 180° C., 130° C. to 180° C., 140° C. to 180° C., 150° C. to 180° C., 160° C. to 180° C., or 170° C. to 180° C. In some embodiments, the temperature may be 25° C. to 180° C., 30° C. to 180° C., 35° C. to 180° C., 40° C. to 180° C., 45° C. to 180° C., 50° C. to 180° C., 55° C. to 180° C., 60° C. to 180° C., 65° C. to 180° C., 70° C. to 180° C., 75° C. to 180° C., 80° C. to 180° C., 85° C. to 180° C., 90° C. to 180° C., 95° C. to 180° C., 100° C. to 180° C., 105° C. to 180° C. , 110° C. to 180° C., 115° C. to 180° C., 120° C. to 180° C., 125° C. to 180° C., 130° C. to 180° C., 135° C. to 180° C., 140° C. to 180° C., 145° C. to 180° C., 150° C. to 180° C., 155° C. to 180° C., 160° C. to 180° C., 165° C. to 180° C., 170° C. to 180° C., or 175° C. to 180° C. In some embodiments, the temperature may be 25° C. to 180° C., 25° C. to 175° C., 25° C. to 170° C., 25° C. to 165° C., 25° C. to 160° C., 25° C. to 155° C., 25° C. to 150° C., 25° C. to 145° C., 25° C. to 140° C., 25° C. to 135° C., 25° C. to 130° C., 25° C. to 125° C., 25° C. to 120° C., 25° C. to 115° C., 25° C. to 110° C., 25° C. to 105° C., 25° C. to 100° C., 25° C. to 95° C., 25° C. to 90° C., 25° C. to 85° C., 25° C. to 80° C., 25° C. to 75° C., 25° C. to 70° C., 25° C. to 65° C., 25° C. to 60° C., 25° C. to 55° C., 25° C. to 50° C., 25° C. to 45° C., 25° C. to 40° C., 25° C. to 35° C., or 25° C. to 30° C.

In some embodiments, the portion of silicon nitride removed in step 104 is at least 80%. In some embodiments, the portion of silicon nitride removed is at least 85%, at least 90%, at least 95%, or at least 99%.

In some embodiments, the composition comprises a phosphoric acid, a water, and an alkyl silane compound of the formula:

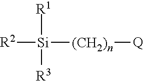

where:
R¹, R², and R³ are each independently a hydrogen, a halide, a hydroxide, an alkyl, or an alkoxide, n is at least 1, and Q is:

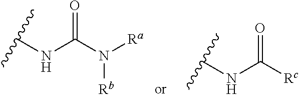

where:
R^{a} and R^{b} are each independently a hydrogen, an alkyl, a cycloalkyl, an aryl, an alkaryl, an aralkyl, or an alkoxyalkyl and Rc is a hydrogen, an alkyl, a cycloalkyl, an aryl, or an alkaryl.

In some embodiments, R¹, R², and R³ are each a methoxy.

In some embodiments, R^{a} and R^{b} are hydrogen.

In some embodiments, R^{a} is hydrogen and R^{b} is an alkyl.

In some embodiments, n is 1 to 6.

In some embodiments, the alkyl silane compound is a compound of the formula:

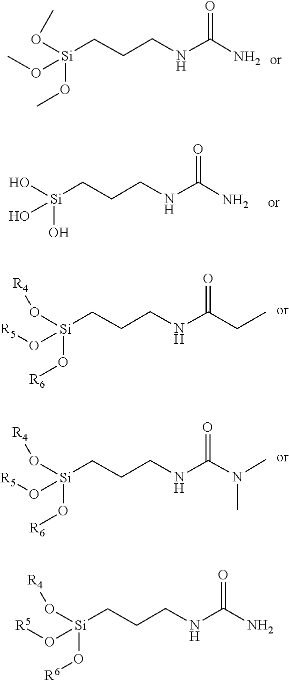

where:
R⁴, R⁵, and R⁶ are independently a methyl, an ethyl, an isopropyl, an n-propyl, an n-butyl, a sec-butyl, a tert-butyl, an isomer thereof.

In some embodiments, the composition comprises 75% to 90% by weight of the phosphoric acid based on a total weight of the composition, or any range or subrange between 75% to 90%. For example, in some embodiments, the percent by weight of phosphoric acid based on the total weight of the composition may be 80% to 90% or 85% to 90%. In some embodiments, the percent by weight of phosphoric acid based on the total weight of the composition may be 76% to 90%, 77% to 90%, 78% to 90%, 79% to 90%, 80% to 90%, 81% to 90%, 82% to 90%, 83% to 90%, 84% to 90%, 85% to 90%, 86% to 90%, 87% to 90%, 88% to 90%, or 89% to 90%. In some embodiments, the percent by weight of phosphoric acid based on the total weight of the wet etch composition may be 75% to 89%, 75% to 88%, 75% to 87%, 75% to 86%, 75% to 85%, 75% to 84%, 75% to 83%, 75% to 82%, 75% to 81%, 75% to 80%, 75% to 79%, 75% to 78%, 75% to 77%, or 75% to 76%.

In some embodiments, the composition comprises 10% to 20% by weight of the water based on a total weight of the composition, or any range or subrange between 1% to 20%. For example, in some embodiments, the percent by weight of the water based on the total weight of the composition may be 1% to 15%, 1% to 10%, or 5% to 20%. In some embodiments, the percent by weight of the water based on the total weight of the composition may be 2% to 20%, 3% to 20%, 4% to 20%, 5% to 20%, 6% to 20%, 7% to 20%, 8% to 20%, 9% to 20%, 10% to 20%, 11% to 20%, 12% to 20%, 13% to 20%, 14% to 20%, 15% to 20%, 16% to 20%, 17% to 20%, 18% to 20%, or 19% to 20%. In some embodiments, the percent by weight of the water based on the total weight of the composition may be 1% to 19%, 1% to 18%, 1% to 17%, 1% to 16%, 1% to 15%, 1% to 14%, 1% to 13%, 1% to 12%, 1% to 11%, 1% to 10%, 1% to 9%, 1% to 8%, 1% to 7%, 1% to 6%, 1% to 5%, 1% to 4%, 1% to 3%, or 1% to 2%.

In some embodiments, the composition comprises 0.01% to 5% by weight of the alkyl silane compound based on a total weight of the composition, or any range or subrange between 0.1% and 5%. For example, in some embodiments, the percent by weight of the alkyl silane compound based on the total weight of the composition may be 1% to 5%, 2% to 5%, 3% to 5%, or 4% to 5%. In some embodiments, the percent by weight of the alkyl silane compound based on the total weight of the composition may be 0.1% to 5%, 0.1% to 4%, 0.1% to 3%, 0.1% to 2%, or 0.1% to 1%. In some embodiments, the percent by weight of the alkyl silane compound based on the total weight of the composition may be 0.1% to 5%, 0.5% to 5%, 1% to 5%, 1.5% to 5%, 2% to 5%, 2.5% to 5%, 3% to 5%, 3.5% to 5%, 4% to 5%, or 4.5% to 5%. In some embodiments, the percent by weight of the alkyl silane compound based on the total weight of the composition may be 0.1% to 5%, 0.1% to 4.5%, 0.1% to 4%, 0.1% to 3.5%, 0.1% to 3%, 0.1% to 2.5%, 0.1% to 2%, 0.1% to 1.5%, 0.1% to 1%, or 0.1% to 0.5%.

In some embodiments, the composition removes a greater proportion of the silicon nitride than the silicon oxide.

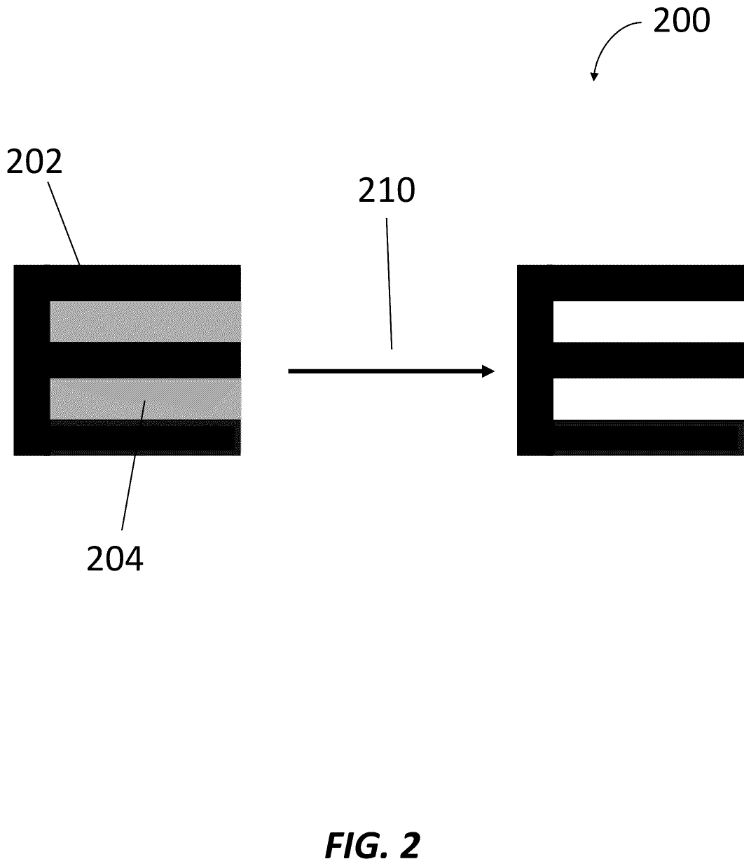

FIG. 2 is an illustration of the results of the method of FIG. 1, according to some embodiments. As shown in FIG. 2, a microelectronic structure with silicon oxide 202 is subjected to a composition 210. The composition 210 may comprise any of the compositions disclosed herein. In some embodiments, the microelectronic structure may be part of a microelectronic device, such as, and without limitation, a 3D NAND structure, flat panel display, microelectromechanical systems (MEMS), integrated circuit, or computer chip.

### EXAMPLE

An improved composition was prepared according to the above formulation, and the performance was compared to a control composition.

The improved composition and the control composition were filled in a measuring cylinder at room temperature, and nitrogen gas was injected into the solution for 1 minute through a nitrogen gas bubbler. The quantity and height of generated bubbles were measured and compared, as shown in Table 1 below.

TABLE 1
Foam Height Comparison

| | | Height of Foam |
|---|---|---|
| Formulation | Process Conditions | Bubbles (mm) |
| Control Composition | 160° C., 200 rpm | 10 |
| Improved Composition | 160° C., 200 rpm | 2 |

As shown, the improved composition markedly improved the height of foam relative to the control composition. The improved composition had a silicon nitride etch rate of 100 Angstroms per min. The improved composition had a silicon oxide etch rate of 0.17 Angstroms per min. Thus, the improved composition had a selectivity of silicon nitride to silicon oxide of 580. This compares favorably with a selectivity of 57 for 85% phosphoric acid.

### ASPECTS

Various Aspects are described below. It is to be understood that any one or more of the features recited in the following Aspect(s) can be combined with any one or more other Aspect(s).

Aspect 1. A composition comprising:
a phosphoric acid;
a water; and
an alkyl silane compound of the formula:

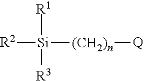

where:
   R¹, R², and R³ are each independently a hydrogen, a halide, a hydroxide, an alkyl, or an alkoxide;
   n is at least 1; and
   Q is:

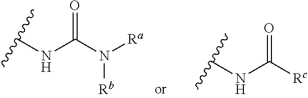

where:
   R^{a} and R^{b} are each independently a hydrogen, an alkyl, a cycloalkyl, an aryl, an alkaryl, an aralkyl, or an alkoxyalkyl; and
   R^{c} is a hydrogen, an alkyl, a cycloalkyl, an aryl, or an alkaryl.
      Aspect 2. The composition according to Aspect 1, wherein R¹, R², and R³ are each a methoxy.
      Aspect 3. The composition according to any one of Aspects 1-2, wherein R^{a} and R^{b} are hydrogen.
      Aspect 4. The composition according to any one of Aspects 1-3, wherein R^{a} is hydrogen and R^{b} is an alkyl.
      Aspect 5. The composition according to any one of Aspects 1-4, wherein n is 1 to 6.
      Aspect 6. The composition according to any one of Aspects 1-5, wherein the alkyl silane compound is a compound of the formula:

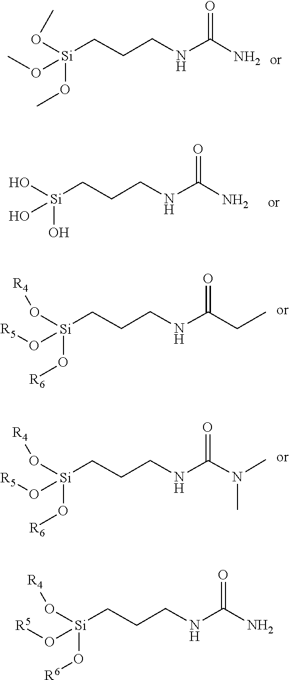

where:
   R⁴, R⁵, and R⁶ are independently a methyl, an ethyl, an isopropyl, an n-propyl, an n-butyl, a sec-butyl, a tert-butyl, an isomer thereof.
      Aspect 7. The composition according to any one of Aspects 1-6, wherein the composition comprises 75% to 90% by weight of the phosphoric acid based on a total weight of the composition.
      Aspect 8. The composition according to any one of Aspects 1-7, wherein the composition comprises 10% to 20% by weight of the water based on a total weight of the composition.
      Aspect 9. The composition according to any one of Aspects 1-8, wherein the composition comprises 0.01% to 5% by weight of the alkyl silane compound based on a total weight of the composition.
      Aspect 10. The composition according to any one of Aspects 1-9, wherein the composition, when mixed at 200 RPM and at 25° C. to 160° C., produces less foam than a composition which does not comprise the alkyl silane compound.
      Aspect 11. A method comprising:
obtaining a structure comprising a silicon nitride and a silicon oxide; and
contacting the structure with a composition to remove at least a portion of the silicon nitride,
   wherein the composition comprises:
      a phosphoric acid;
      a water; and
      an alkyl silane compound of the formula:

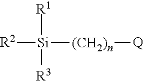

where:
   R¹, R², and R³ are each independently a hydrogen, a halide, a hydroxide, an alkyl, or an alkoxide;
   n is at least 1; and
   Q is:

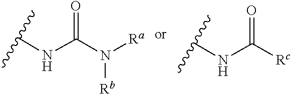

where:
   R^{a} and R^{b} are each independently a hydrogen, an alkyl, a cycloalkyl, an aryl, an alkaryl, an aralkyl, or an alkoxyalkyl; and
   R^{c} is a hydrogen, an alkyl, a cycloalkyl, an aryl, or an alkaryl.
      Aspect 12. The method according to Aspects 11, wherein R¹, R², and R³ are each a methoxy.
      Aspect 13. The method according to any one of Aspects 11-12, wherein R^{a} and R^{b} are hydrogen.
      Aspect 14. The method according to any one of Aspects 11-13, wherein R^{a} is hydrogen and Rb is an alkyl.
      Aspect 15. The method according to any one of Aspects 11-14, wherein n is 1 to 6.
      Aspect 16. The composition according to any one of Aspects 11-55, wherein the alkyl silane compound is a compound of the formula:

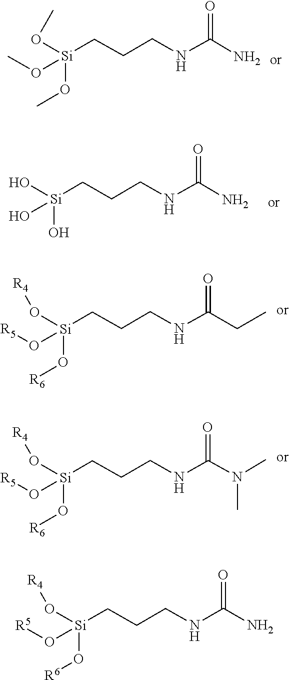

where:
   R⁴, R⁵, and R⁶ are independently a methyl, an ethyl, an isopropyl, an n-propyl, an n-butyl, a sec-butyl, a tert-butyl, an isomer thereof.

Aspect 17. The method according to any one of Aspects 11-16, wherein the composition comprises 75% to 90% by weight of the phosphoric acid based on a total weight of the composition.

Aspect 18. The method according to any one of Aspects 11-17, wherein the composition comprises 10% to 20% by weight of the water based on a total weight of the composition.

Aspect 19. The method according to any one of Aspects 11-18, wherein the composition comprises 0.01% to 5% by weight of the alkyl silane compound based on a total weight of the composition.

Aspect 20. The method according to any one of Aspects 11-19, wherein the composition removes a greater proportion of the silicon nitride than the silicon oxide.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A composition comprising:
a phosphoric acid;
a water; and
an alkyl silane compound of the formula: 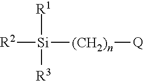
where:
R¹, R², and R³ are each independently a hydrogen, a halide, a hydroxide, an alkyl, or an alkoxide;
n is at least 1; and
Q is: 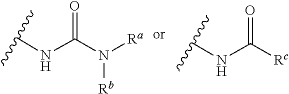
where:
R^{a} and R^{b} are each independently a hydrogen, an alkyl, a cycloalkyl, an aryl, an alkaryl, an aralkyl, or an alkoxyalkyl; and
R^{c} is a hydrogen, an alkyl, a cycloalkyl, an aryl, or an alkaryl.

2. The composition of claim 1, wherein R¹, R², and R³ are each a methoxy.

3. The composition of claim 1, wherein R^{a} and R^{b} are hydrogen.

4. The composition of claim 1, wherein R^{a} is hydrogen and R^{b} is an alkyl.

5. The composition of claim 1, wherein n is 1 to 6.

6. The composition of claim 1, wherein the alkyl silane compound is a compound of the formula: 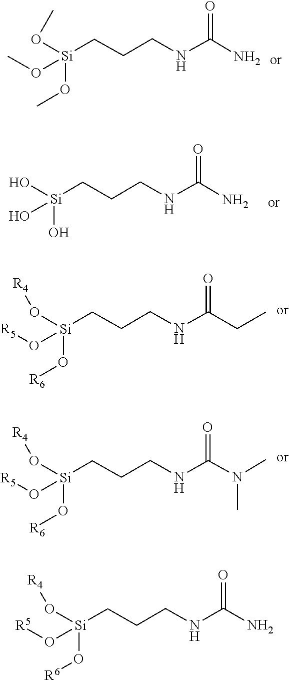
where:
R⁴, R⁵, and R⁶ are independently a methyl, an ethyl, an isopropyl, an n-propyl, an n-butyl, a sec-butyl, a tert-butyl, an isomer thereof.

7. The composition of claim 1, wherein the composition comprises 75% to 90% by weight of the phosphoric acid based on a total weight of the composition.

8. The composition of claim 1, wherein the composition comprises 10% to 20% by weight of the water based on a total weight of the composition.

9. The composition of claim 1, wherein the composition comprises 0.01% to 5% by weight of the alkyl silane compound based on a total weight of the composition.

10. The composition of claim 1, wherein the composition, when mixed at 200 RPM and at 25° C. to 160° C., produces less foam than a composition which does not comprise the alkyl silane compound.

11. A method comprising:
obtaining a structure comprising a silicon nitride and a silicon oxide; and
contacting the structure with a composition to remove at least a portion of the silicon nitride,
wherein the composition comprises:
a phosphoric acid;
a water; and
an alkyl silane compound of the formula: 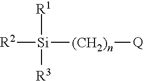
where:
R¹, R², and R³ are each independently a hydrogen, a halide, a hydroxide, an alkyl, or an alkoxide;
n is at least 1; and
Q is: 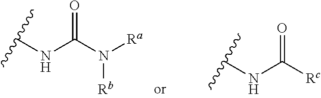
where:
R^{a} and R^{b} are each independently a hydrogen, an alkyl, a cycloalkyl, an aryl, an alkaryl, an aralkyl, or an alkoxyalkyl; and
R^{c} is a hydrogen, an alkyl, a cycloalkyl, an aryl, or an alkaryl.

12. The method of claim 11, wherein R¹, R², and R³ are each a methoxy.

13. The method of claim 11, wherein R^{a} and R^{b} are hydrogen.

14. The method of claim 11, wherein R^{a} is hydrogen and R^{b} is an alkyl.

15. The method of claim 11, wherein n is 1 to 6.

16. The method of claim 11, wherein the alkyl silane compound is a compound of the formula: 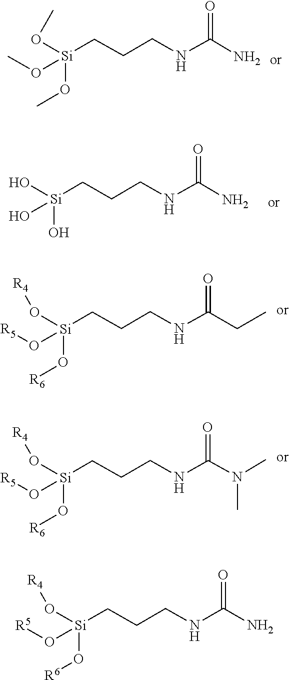
where:
R⁴, R⁵, and R⁶ are independently a methyl, an ethyl, an isopropyl, an n-propyl, an n-butyl, a sec-butyl, a tert-butyl, an isomer thereof.

17. The method of claim 11, wherein the composition comprises 75% to 90% by weight of the phosphoric acid based on a total weight of the composition.

18. The method of claim 11, wherein the composition comprises 10% to 20% by weight of the water based on a total weight of the composition.

19. The method of claim 11, wherein the composition comprises 0.01% to 5% by weight of the alkyl silane compound based on a total weight of the composition.

20. The method of claim 11, wherein the composition removes a greater proportion of the silicon nitride than the silicon oxide.
